(19) United States
(12) Patent Application Publication
(10) Pub. No.: US 2025/0356097 A1
(43) Pub. Date: Nov. 20, 2025

(54) METHODS AND SYSTEM FOR CONFIGURING AN ADVANCED ELECTRONIC CIRCUIT BOARD WITH OPTIMIZED COMPONENT LAYOUT AND ENHANCED SIGNAL INTEGRITY FOR DATA PROCESSING EFFICIENCY AND COMMUNICATION SPEED

(71) Applicant: Penguin Computing, Inc., Fremont, CA (US)

(72) Inventors: Zach Schimke, Tempe, AZ (US); Philip Pokorny, Dublin, CA (US); John Casu, Half Moon Bay, CA (US); George Zemke, Chandler, AZ (US)

(73) Assignee: Penguin Computing, Inc., Fremont, CA (US)

(21) Appl. No.: 18/669,087

(22) Filed: May 20, 2024

(51) Int. Cl. G06F 30/392

(52) U.S. Cl. CPC G06F 30/392

(57) ABSTRACT

Methods and systems of configuring a printed circuit board includes setting onto a substrate of a printed circuit board a plurality of distinct sets of processing nodes, wherein setting the plurality of distinct sets of processing nodes includes arranging pairs of parallel processing nodes onto the substrate of the printed circuit board, each of the pairs of parallel nodes including a first set of processing nodes being arranged parallel to a second set of processing nodes of the plurality of distinct sets of processing nodes, setting a plurality of interconnect switches, wherein setting the plurality of interconnect switches includes centrally interposing one of the plurality of interconnect switches between each of the pairs of parallel processing nodes, and setting a plurality of microcontrollers along a peripheral region of the substrate of the printed circuit board surrounding the plurality of distinct sets of processing nodes.

### TECHNICAL FIELD

This invention relates generally to the field of electronic circuit design, and more particularly to a method for arranging processing nodes and interconnect switches on a printed circuit board to optimize data processing efficiency and communication speed.

### BACKGROUND

Printed circuit boards are fundamental components in modern electronic devices, providing mechanical support and electrical connections for various electronic components. Conventional printed circuit board designs often face challenges related to space utilization, signal integrity, thermal management, and scalability.

Specifically, the configuration or layout of components on a printed circuit board can significantly impact the overall system performance. Traditional printed circuit board layouts fail to adequately address the needs for rapid data transfer and efficient spatial arrangement, particularly in high-performance computing environments where data coherence and processing speed may be critical.

Thus, there is a need in the electronic circuit design field to create an improved circuit component design and layout for electronic circuit boards that enable dynamic management of circuit components that may be reconfigurable for different applications and that also enhance the speed and quality of signal communication between various circuit components of a given electronic circuit board. The embodiments of the present application provide technical solutions that address, at least, the needs described above, as well as the deficiencies of the state of the art.

### BRIEF SUMMARY OF THE INVENTION(S)

In one embodiment, a method of configuring a printed circuit board, the method includes setting onto a substrate of a printed circuit board (A) a plurality of distinct sets of processing nodes, wherein setting the plurality of distinct sets of processing nodes includes arranging one or more pairs of parallel processing nodes onto the substrate of the printed circuit board, each of the one or more pairs of parallel nodes including a first set of processing nodes being arranged parallel to a second set of processing nodes of the plurality of distinct sets of processing nodes; (B) a plurality of interconnect switches,

wherein setting the plurality of interconnect switches includes centrally interposing one of the plurality of interconnect switches between each of the one or more pairs of parallel processing nodes; and (C) a plurality of microcontrollers along a peripheral region of the substrate of the printed circuit board surrounding the plurality of distinct sets of processing nodes.

In one embodiment, the method further includes (D) setting onto the substrate of the printed circuit board a plurality of sets of interconnect cables, wherein setting the plurality of sets of interconnect cables includes arranging a first set of interconnect cables adjacent a side of a first interconnect switch of the plurality of interconnect switches and arranging a second set of interconnect cables adjacent a side of a second interconnect switch of the plurality of interconnect switches.

In one embodiment, the first set of interconnect cables being configured to operate a first data transfer protocol, and the second set of interconnect cables being configured to operate a second data transfer protocol that is distinct from the first data transfer protocol.

In one embodiment, each distinct set of the plurality of distinct sets of processing nodes includes a linear array of processing nodes sequentially disposed on the substrate of the printed circuit board.

In one embodiment, the first set of processing nodes of a first of the one or more pairs of parallel processing nodes includes a first linear array of processing nodes; the second set of processing nodes of the first of the one or more pairs of parallel processing nodes includes a second linear array of processing nodes; a linear extent of the first linear array of processing nodes is arranged parallel to a linear extent of the second linear array of processing nodes; and interposing the one of the plurality of interconnect switches between each of the one or more pairs of parallel processing nodes includes interposing a first interconnect switch of the plurality of interconnect switches between the first linear array of processing nodes and the second linear array of processing nodes.

In one embodiment, setting the plurality of interconnect switches further includes: positioning a first interconnect switch of the plurality of interconnect switches offset an axis centrally bisecting the first linear array of processing nodes and the second linear array of processing nodes that are parallelly disposed onto the substrate of the printed circuit board.

In one embodiment, the first set of processing nodes of a second of the one or more pairs of parallel processing nodes includes a first linear array of processing nodes; the second set of processing nodes of the second of the one or more pairs of parallel processing nodes includes a second linear array of processing nodes; a linear extent of the first linear array of processing nodes is arranged parallel to a linear extent of the second linear array of processing nodes; and interposing the one of the plurality of interconnect switches between each of the one or more pairs of parallel processing nodes includes interposing a second interconnect switch of the plurality of interconnect switches between the first linear array of processing nodes and the second linear array of processing nodes of the second of the one or more pairs of parallel processing nodes.

In one embodiment, setting the plurality of interconnect switches further includes centrally aligning a first interconnect switch with a second interconnect switch of the plurality of interconnect switches.

In one embodiment, the method further includes configuring one or more free spaces on the substrate of the printed circuit board between each processing node of a given linear array of processing nodes and at least one interconnect switch of the plurality of interconnect switches, wherein the one or more free spaces exclude electrical obstructions.

In one embodiment, the gap on the substrate of the printed circuit board excludes a placement of electrical components between each processing node of the given linear array of processing nodes and the at least one interconnect switch of the plurality of interconnect switches.

In one embodiment, each of the plurality of microcontrollers is arranged adjacent one distinct set of processing nodes of the plurality of distinct sets of processing nodes.

In one embodiment, a method of configuring an electronic circuit board, the method comprising: integrating onto a substrate of an electronic circuit board: (A) a plurality of distinct sets of processing circuits, wherein integrating the plurality of distinct sets of processing circuits includes arranging one or more pairs of parallel processing circuits onto the substrate of the electronic circuit board, each of the one or more pairs of parallel circuits including a first set of processing circuits being arranged parallel to a second set of processing circuits of the plurality of distinct sets of processing circuits; (B) a plurality of interconnect switches, wherein integrating the plurality of interconnect switches includes centrally interposing one of the plurality of interconnect switches between each of the one or more pairs of parallel processing circuits; and (C) a plurality of microcontrollers along a peripheral region of the substrate of the electronic circuit board surrounding the plurality of distinct sets of processing circuits.

In one embodiment, the method further includes (D) integrating onto the substrate of the electronic circuit board a plurality of sets of interconnect cables, wherein integrating the plurality of sets of interconnect cables includes arranging a first set of interconnect cables adjacent a side of a first interconnect switch of the plurality of interconnect switches and arranging a second set of interconnect cables adjacent a side of a second interconnect switch of the plurality of interconnect switches.

In one embodiment, the first set of interconnect cables being configured to operate a first data transfer protocol, and the second set of interconnect cables being configured to operate a second data transfer protocol that is distinct from the first data transfer protocol.

In one embodiment, each distinct set of the plurality of distinct sets of processing circuits includes a series array of processing circuits sequentially disposed on the substrate of the electronic circuit board.

In one embodiment, the first set of processing circuits of a first of the one or more pairs of parallel processing circuits includes a first series array of processing circuits; the second set of processing circuits of the first of the one or more pairs of parallel processing circuits includes a second series array of processing circuits; a series extent of the first series array of processing circuits is arranged parallel to a series extent of the second series array of processing circuits; and interposing the one of the plurality of interconnect switches between each of the one or more pairs of parallel processing circuits includes interposing a first interconnect switch of the plurality of interconnect switches between the first series array of processing circuits and the second series array of processing circuits.

In one embodiment, integrating the plurality of interconnect switches further includes: positioning a first interconnect switch of the plurality of interconnect switches offset an axis centrally bisecting the first series array of processing circuits and the second series array of processing circuits that are parallelly disposed onto the substrate of the electronic circuit board.

In one embodiment, the first set of processing circuits of a second of the one or more pairs of parallel processing circuits includes a first series array of processing circuits; the second set of processing circuits of the second of the one or more pairs of parallel processing circuits includes a second series array of processing circuits; a series extent of the first series array of processing circuits is arranged parallel to a series extent of the second series array of processing circuits; and interposing the one of the plurality of interconnect switches between each of the one or more pairs of parallel processing circuits includes interposing a second interconnect switch of the plurality of interconnect switches between the first series array of processing circuits and the second series array of processing circuits of the second of the one or more pairs of parallel processing circuits.

In one embodiment, the method further includes configuring one or more free spaces on the substrate of the electronic circuit board between each processing circuit of a given series array of processing circuits and at least one interconnect switch of the plurality of interconnect switches, wherein the one or more free spaces exclude electrical obstructions, wherein the gap on the substrate of the electronic circuit board excludes a placement of electrical components between each processing circuit of the given series array of processing circuits and the at least one interconnect switch of the plurality of interconnect switches.

In one embodiment, a method includes placing onto a substrate of an electronic circuit board (A) a plurality of distinct sets of processing circuits, wherein placing the plurality of distinct sets of processing circuits includes arranging one or more pairs of parallel processing circuits onto the substrate of the electronic circuit board, each of the one or more pairs of parallel circuits including a first set of processing circuits being arranged parallel to a second set of processing circuits of the plurality of distinct sets of processing circuits; (B) a plurality of interconnect switches, wherein placing the plurality of interconnect switches includes centrally interposing one of the plurality of interconnect switches between each of the one or more pairs of parallel processing circuits; (C) a plurality of microcontrollers along a peripheral region of the substrate of the electronic circuit board surrounding the plurality of distinct sets of processing circuits; and (D) placing onto the substrate of the electronic circuit board a plurality of sets of interconnect cables, wherein placing the plurality of sets of interconnect cables includes arranging a first set of interconnect cables adjacent a side of a first interconnect switch of the plurality of interconnect switches and arranging a second set of interconnect cables adjacent a side of a second interconnect switch of the plurality of interconnect switches.

### BRIEF DESCRIPTION OF THE FIGURES

FIG. 1 is a schematic representation of a printed circuit board, in accordance with one or more embodiments of the present application.

FIG. 2 illustrates an example method in accordance with one or more embodiments of the present application;

FIG. 3 illustrates an exemplary schematic of an offset arrangement of interconnect switches on an electronic circuit board in accordance with one or more embodiments of the present application;

FIG. 4 illustrates an exemplary schematic of an arrangement of microcontrollers relative to processing nodes on an electronic circuit board in accordance with one or more embodiments of the present application;

FIG. 5 illustrates an exemplary schematic of an arrangement of interconnect cables relative to interconnect switches on an electronic circuit board in accordance with one or more embodiments of the present application;

FIG. 6 illustrates an exemplary schematic of arrangement of an interconnect switch relative to multiple series of processing nodes in accordance with one or more embodiments of the present application; and

FIG. 7 illustrates an exemplary schematic of arrangement of an interconnect switch relative to a first array and a second array of processing nodes in accordance with one or more embodiments of the present application.

### DESCRIPTION OF THE PREFERRED EMBODIMENTS

The following description of the preferred embodiments of the invention is not intended to limit the invention to these preferred embodiments, but rather to enable any person skilled in the art to make and use this invention.

### 1. Architecture of an Enhanced Design of an Electronic Circuit Board

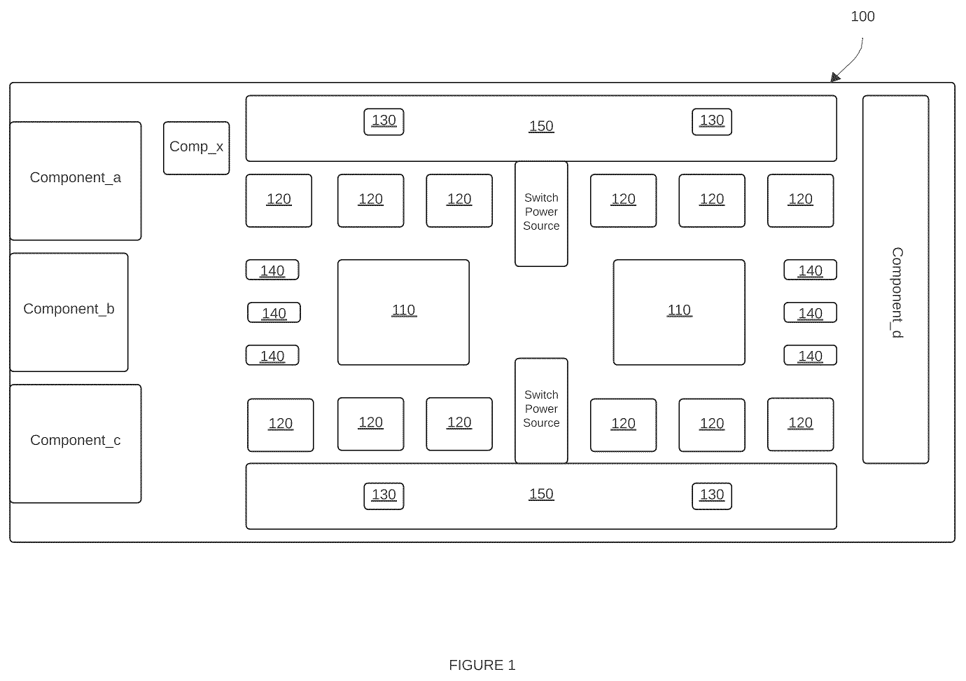

As shown by reference to FIG. 1, a printed circuit board 100 with an enhanced component layout for optimized signal integrity and speed includes a plurality more interconnect switches 110, a plurality of processing nodes 120, a plurality of microcontrollers 130, a plurality of interconnect cables 140, and power sources 150.

The printed circuit board 100 preferably includes substrate material that may be composed of a high-grade, flame-resistant, glass-reinforced epoxy laminate or the like that provides structural integrity and electrical insulation between conductive layers. In one or more embodiments, a design or a layout of conductive traces, component pads, and connectivity features may be optimized for enhanced signal integrity and minimizing electromagnetic interference.

### 1.1 Interconnect Switches

The plurality of interconnect switches 110 may function to direct a flow of electrical signals through predetermined paths on the printed circuit board 100. The plurality of interconnect switches 110 enables dynamic switching between different circuit configurations in which multiple functionalities are embedded into a single system or the like. The plurality of interconnect switches 110 may include any suitable switch circuit including, but not limited to, mechanical relays, solid state switches, multiplexers, and the like.

In one or more embodiments, one or more of the plurality of interconnect switches 110 may operate using the PCI express (PCIe) protocol implementing high-speed serial computer expansion bus standard to connect devices on the printed circuit board 100 to peripheral devices or external devices. In such embodiments, one or more of the plurality of interconnect switches operating using the PCIe protocol may function to manage communication paths without requiring routing through a central processor thereby reducing latency and enabling an efficient use of CPU resources for other tasks.

In one or more embodiments, the one or more of the plurality of interconnect switches operating using the PCIe protocol may include one or more ports 111 dedicated for PCIe communications and a plurality of ports 113 dedicated to host devices on the printed circuit board 100, such as processing nodes 120.

In one or more embodiments, one or more of the plurality of interconnect switches 110 may operate using the Compute Express Link (CXL) protocol enabling high-speed, efficient data transfer between a plurality of host processors, such as processing nodes 110 and computing components including, but not limited to, accelerators, memory buffers, and specific I/O devices. In such embodiments, one or more of the plurality of interconnect devices 110 operating as a CXL switch preferably function to manage coherency between the processing nodes 120 and memory domains of connected devices.

In one or more embodiments, the one or more of the plurality of interconnect switches operating using the CXL protocol may include one or more ports 112 dedicated for PCIe communications and a plurality of ports 114 dedicated to host devices on the printed circuit board 100, such as processing nodes 120.

### 1.2 Processing Nodes

The plurality of processing nodes 120, which may sometimes be referred to herein as processing circuits, preferably includes one or more groups of components along the printed circuit board 100 that may be dedicated to handling computational tasks. In one or more embodiments, each of the plurality of processing nodes 120 may include one or more central processing units, one or more accelerators, memory circuits or modules, input/output data ports, and/or components that operate in concert to process data, move data, and execute computer instructions.

In one or more embodiments, the plurality of processing nodes 120 may be grouped and arranged on the printed circuit board 100 in various arrangements that allow for an optimized layout. As a non-limiting example, one or more linear array of processing nodes may be arranged along the printed circuit board 100 adjacent or proximate to one or more of the plurality of interconnect switches 110 to shorten a routing path for conductive materials (e.g., electrical traces).

### 1.3 SoC Microcontrollers

The plurality of microcontrollers 130, which sometimes may be referred to herein as system-on-chip (SoC) microcontrollers, may operate to manage power distribution to sets or series of processing nodes of the plurality of processing nodes 120. Each microcontroller of the plurality of microcontrollers 130 may be conductively connected to a distinct set of processing nodes on the printed circuit board 110 for dynamically managing the power requirements of the set of processing nodes. In a preferred embodiment, a given microcontroller of the plurality of microcontrollers 130 may manage the power distribution to multiple processing nodes within a given set of processing nodes in a parallel or substantially parallel manner. That is, in such embodiments, based on workload data observed and/or various environmental and system conditions (e.g., temperature) by the given microcontroller for each processing node of the given set of processing nodes, the microcontroller may function to compute an optimal power requirement to be applied, at the same time or substantially the same time, to all of the processing nodes within the given set of processing nodes. In such embodiments, the given microcontroller may adjust a voltage and/or a frequency of corresponding processing nodes according to real-time processing demands using dynamic voltage and frequency scaling techniques. Additionally, or alternatively, the plurality of microcontrollers 130 may apply power gating and/or clock gating techniques to reduce power consumption of the plurality of processing nodes 130.

In one or more embodiments, each microcontroller of the plurality of microcontrollers 130 may be connected to a power source 150 and operate the controlling conduit to a set of processing nodes of the plurality of processing nodes 120. In a preferred embodiment, each microcontroller of the plurality of microcontrollers 130 may include at least one central processing unit, an integrated power management unit, a memory, a clock management module, and a communication interface that enables the dynamic management of the plurality of processing nodes 120.

### 1.4 Interconnect Cables

The plurality of interconnect cables 140 preferably operate to connect to one or more of the plurality of interconnect switches 130 for power transmission, signal transmission, and/or data transmissions. The plurality of interconnect cables 140 preferably comprise modular interconnect (MICO) cables having a modular design enabling flexible configurations in cabling and connectivity for various requirements and/or environments.

In one or more embodiments, the plurality of interconnect cables 140 may enable the plurality of interconnect switches 130 to configurably operate using multiple and/or distinct communication protocols. As a non-limiting example, a first set of interconnect cables of the plurality of interconnect cables 140 may enable a first interconnect switch on a printed circuit board to operate using PCIe protocol and a second set of interconnect cables of the plurality of interconnect cables 140 may enable a second interconnect switch on the printed circuit board to operate using CXL protocol. In this non-limiting example, a type of the interconnect cable installed next to a given interconnect switch may govern an operational mode of the interconnect switch, whether PCIe or CXL, allowing for dynamic configuration based on the specific application needs.

### 2. Method of Configuring an Electronic Circuit Board

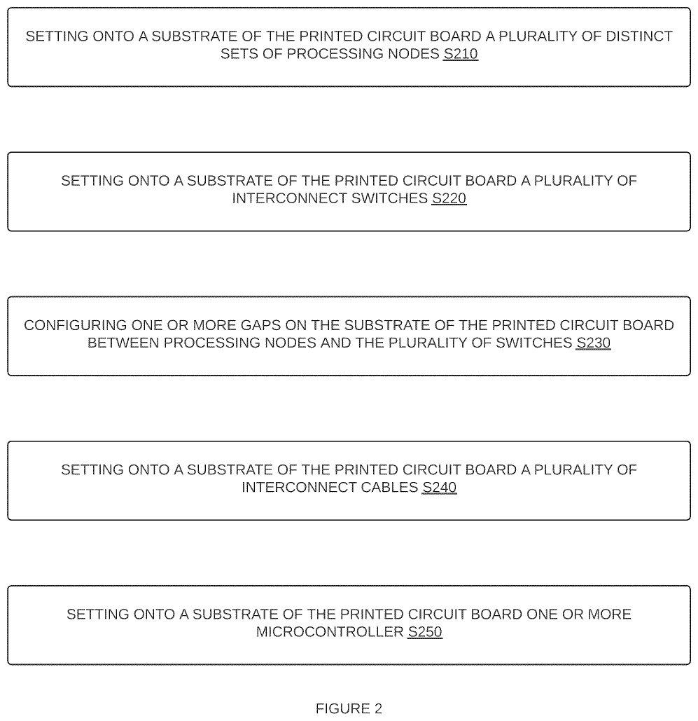

As shown by reference in FIG. 2, method 200 of configuring a printed circuit board includes setting onto a substrate of the printed circuit board a plurality of distinct sets of processing nodes S210, setting on the substrate of the printed circuit board a plurality of interconnect switches S220, configuring one or more gaps on the substrate of the printed circuit board between processing nodes and the plurality of interconnect switches S230, setting onto the substrate of the printed circuit board a plurality of interconnect cables S240, and setting onto the substrate of the printed circuit board one or more (SoC) microcontrollers S250.

2.1 Configuring Processing Nodes onto the PCB

S210, which includes setting on a substrate of a printed circuit board a plurality of distinct sets of processing nodes, may include arranging multiple series of processing nodes along a plurality of distinct locations on the printed circuit board. In a preferred embodiment, the positioning of each of the series or groups of processing nodes allows for an optimal positioning of the processing nodes relative to a position of the plurality of interconnect switches. In this way, the proximate or adjacent positioning of the processing nodes to the interconnect switches allows for the most efficient route planning for conductive connections or traces between the processing nodes and interconnect switches for improved signal communication speed and quality.

In one or more embodiments, each series of processing nodes may include N processing nodes arranged in a linear array or the like, where N represents the number of processing nodes within the linear array. The N processing nodes within the linear array of each series of processing nodes preferably are aligned along a central axis. In one non-limiting example, in which N is three, each series of processing nodes may include three processing nodes arranged in a linear array.

Additionally, or alternatively, in such embodiments, according to a two-dimensional coordinate system (e.g., X-Y, East/West—North/South), setting the plurality of distinct sets of processing nodes onto the substrate may include arranging each linear array of processing nodes along an East/West orientation of the printed circuit board. In one or more embodiments, the printed circuit board may have a rectangular shape in which a longer extent of the printed circuit board may be considered the East/West orientation and the short extent of the printed circuit board may be considered the North/South orientation. In such embodiments, process S210 may arrange each of the plurality of distinct sets of processing nodes onto the printed circuit board such that each distinct linear array of processing nodes is arranged along the longer extent of the printed circuit board, which may be the East/West orientation of the printed circuit board.

2.2 Configuring Interconnect Switches onto the PCB

S220, which includes setting on the substrate of the printed circuit board a plurality of interconnect switches, may include arranging two or more interconnect switches along an extent of the printed circuit board to enable high throughput communication between devices on the printed circuit board and/or devices off the printed circuit board. In one or more embodiments, the interconnect switches are configurable to operate as either PCIe switches or CXL switches. In such embodiments, a mode of operation of the interconnect switches may be determined by the type of interconnect cable (e.g., Modular Interconnect Cable Optimized (MICO)) that may be on the substrate of the printed circuit board, as described in more detail below.

In a preferred embodiment, setting the plurality of interconnect switches on the substrate of the printed circuit board includes centrally interposing each one of the plurality of interconnect switches between each of a distinct pair of a plurality of distinct sets of processing nodes. In such embodiments, a given interconnect switch may be installed onto the substrate equidistant from a first set of processing nodes in a linear arrangement and a second set of processing nodes in a linear arrangement of a parallel set of processing nodes. In this way, a routing distance for installing electrical traces between the first set of processing nodes and the interconnect switch and the second set of processing nodes and the interconnect switch may be approximately the same.

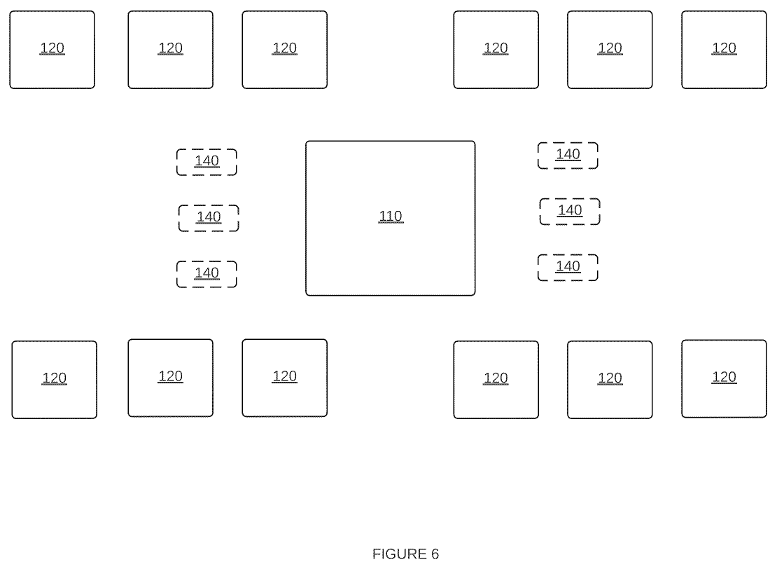

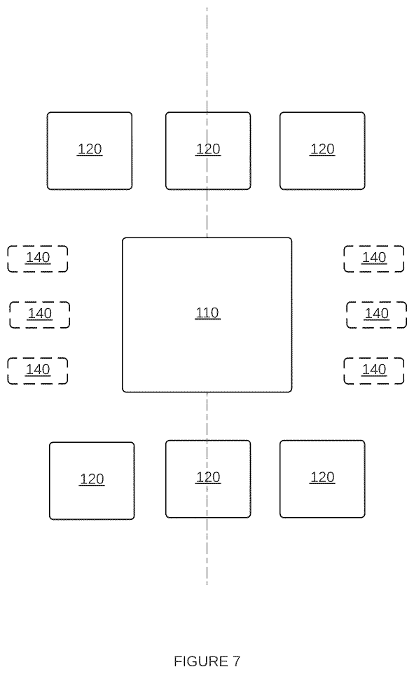

Additionally, or alternatively, in some embodiments, S220 may include setting a single interconnect switch between a first array of processing nodes and a second array of processing nodes, as shown by way of example in FIG. 7. In such embodiments, the first array of processing nodes may be set parallel to the second array of processing nodes while the single interconnect switch may be centrally interposed between the first and second array of processing nodes. In a further variation, as shown by way of example in FIG. 6, a single interconnect switch may be interposed between multiple, parallel arrays of processing nodes. In this further variation, a plurality of interconnect cables may be optionally arranged on either side of the interconnect switch thereby enabling an execution of one or more distinct data transfer protocols.

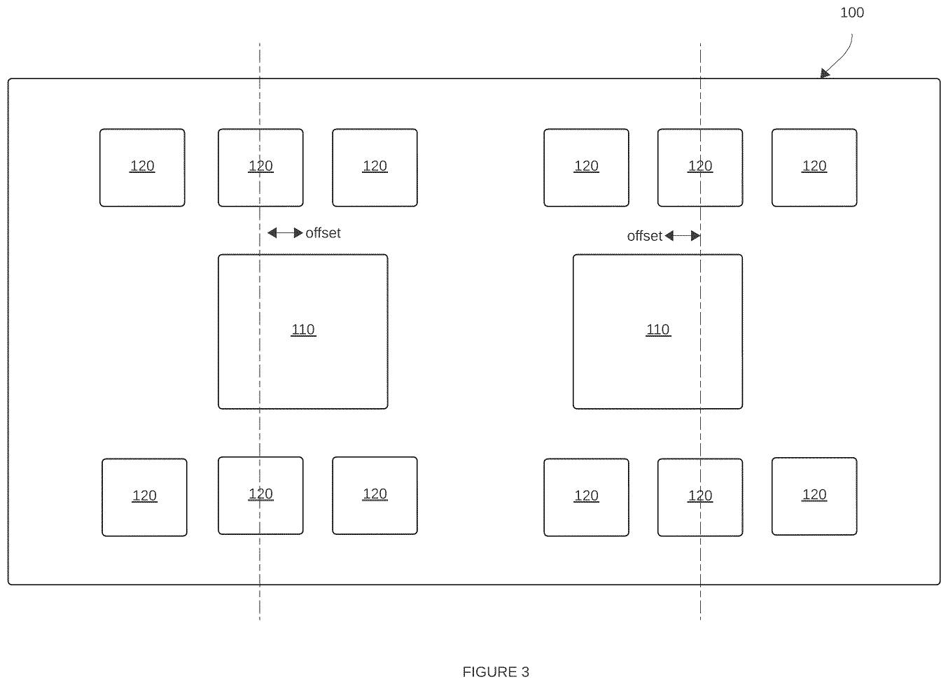

While, in some embodiments, each interconnect switch may be centrally positioned between two series of processing nodes to facilitate balanced data communication or signal speeds, in alternative embodiments, S220 may enable a configuration that allows for an offset placement of each interconnect switch relative to the two series of processing nodes, as shown by way of example in FIG. 3. In such embodiments, setting each interconnector switch onto the substrate of the printed circuit board may include positioning a first interconnect switch offset an axis centrally bisecting the two parallel series or two parallel linear arrays of processing nodes. In a preferred embodiment, the offset direction of the interconnect switch is preferably towards a center position of the printed circuit board bias towards another interconnect switch that may also be centrally interposed between a distinct pair of two parallel linear arrays of processing nodes.

At least one technical advantage of the offset and/or biased arrangement of each of the interconnect switches toward a second pair of parallel processing nodes may be designed to minimize a distance that electrical traces must travel from each processing node of the second pair to the interconnect switch thereby reducing an extent of the routing lane from the farthest processing node of the second pair of processing nodes to the interconnect switch. Moreover, the strategic positioning of the interconnect switch in this offset placement may function to reduce signal degradation and latency, thereby enhancing the overall efficiency of data transfer across the printed circuit board.

2.3 Configuring Gaps within the PCB

S230, which includes configuring free spaces or routing gaps on the printed circuit board, may include designing one or more free spaces on the substrate of the printed circuit board between each processing node of a given linear array of processing nodes and at least one interconnect switch on the printed circuit board. Accordingly, in one or more embodiments, S230 may function to design the printed circuit board with strategically positioned routing gaps or free spaces on the substrate, which may be devoid of vias, components, or other electrical obstructions. The absence of vias or other components within the free space regions of the printed circuit board may function to facilitate the routing of electrical traces without physical or electrical interferences, which can often be a source of signal degradation or degraded communication speeds.

Additionally, or alternatively, configuring free spaces or routing gaps on the printed circuit board includes identifying one or more optimal routing paths for electrical traces between a position of the processing nodes and each of a position of each of the interconnect switches of the printed circuit board. Preferably, each of the one or more optimal routing paths include the shortest and most direct routes between each respective processing node and each interconnect switch. During a configuration phase of the printed circuit board, designating on a layout of the printed circuit board the identified one or more optimal routing paths as free spaces or routing gaps and excluding a placement of electrical components, vias, and/or physical components within the free spaces or the routing gaps.

Additionally, or alternatively, each of the designated free spaces or routing gaps between the processing nodes and the interconnect switches allow for more direct and unobstructed paths for electrical traces. In such embodiments, the direct routing minimizes the length of the electrical traces and thus, reduces potential signal degradation or latency, which may be critical for maintaining high-speed communication between the processing nodes and the interconnect switches.

Additionally, or alternatively, the optimization of the design of the printed circuit board with the free spaces or routing gaps, reduces electromagnetic interference and cross-talk between electrical traces, further enhancing the signal integrity and overall reliability of the printed circuit board.

Free PCB space without any vias to configure a large number of traces because of having to connect each switch to each device. So that we could run traces long distances without having to route around things.

2.4 Configuring MICO Cables onto the PCB

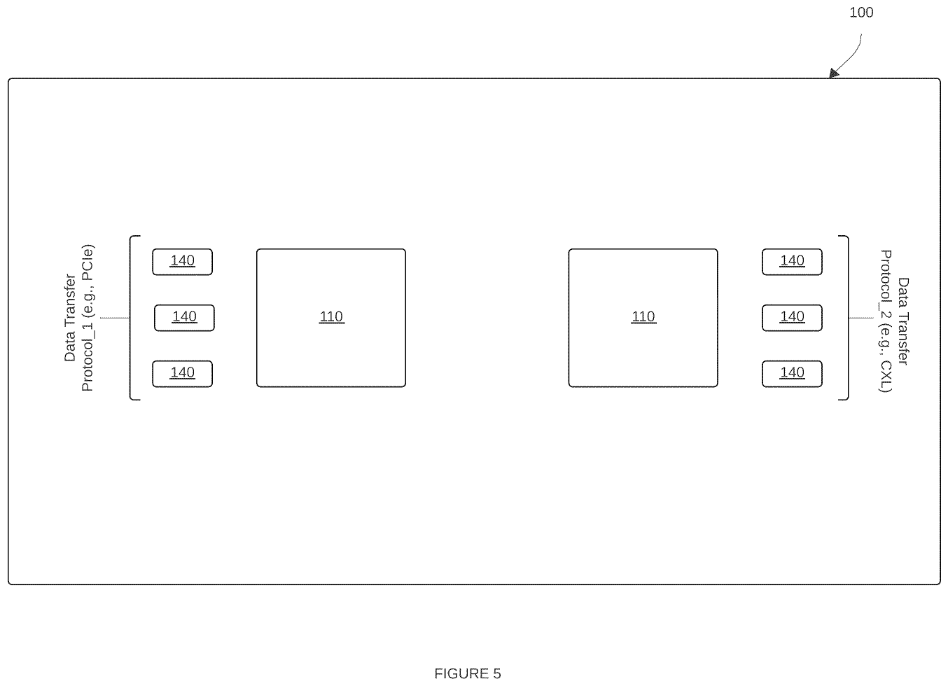

S240, which includes setting onto the substrate of the printed circuit board a plurality of interconnect cables, may function to install multiple sets of interconnect cables onto the printed circuit board that enable one or more of the plurality of interconnect switches to operate using different communication protocols, as shown by way of example in FIG. 5. In a preferred embodiment, the interconnect cables comprise modular interconnect cable optimized (MICO) connectors. In such embodiments, the interconnector cables may be arranged adjacent to each respective interconnect switch thereby providing the flexibility to adapt the data transfer protocol and support multiple communication protocols based on specific performance requirements or system configurations of the printed circuit board. That is, the method 200 enhances an adaptability of the printed circuit board to different configurations and requirements, allowing for easy modifications and upgrades without compromising on performance.

In one or more embodiments, setting the plurality of interconnect cables onto the printed substrate includes arranging a series of interconnect cables proximate or adjacent to each of the plurality of interconnect switches based on a predetermined linear arrangement of the series of interconnect cables and side orientation of the interconnect switch. In such embodiments, the series of interconnect cables may include two or more interconnect cables that may be linearly arranged adjacent to a corresponding number of ports of a respective interconnect switch of the plurality of interconnect switches. In operation, each series of interconnect cables enables its respective interconnect switch to operate using different communication protocols. As a non-limiting example, a first interconnect switch may use a first set of interconnect cables to support or operate PCIe protocols, while a second interconnect switch using a second set of interconnect cables may operate with CXL protocols. In this way, the execution of S240 may enable flexibility in a configuration of the printed circuit board for various operational needs.

Additionally, or alternatively, in one or more embodiments, each series of interconnect cables of the plurality of interconnect cables may be installed or positioned adjacent to a side of a respective interconnect switch that is not biased or offset towards another interconnect switch. In such embodiments, positioning the interconnect cables in this manner enables clear segregation between different interconnect switches and their associated interconnect cables thereby minimizing potential interference and optimizing the physical layout of the printed circuit board for improved signal integrity.

2.5 Configuring SoC MCs onto the PCB

S250, which includes setting on the substrate of the printed circuit board a plurality of system-on-chip (SoC) microcontrollers, may include strategically placing the plurality of microcontrollers along peripheral surface regions of the substrate of the printed circuit board, surrounding or encompassing the plurality of processing nodes that may be centrally located on the printed circuit board.

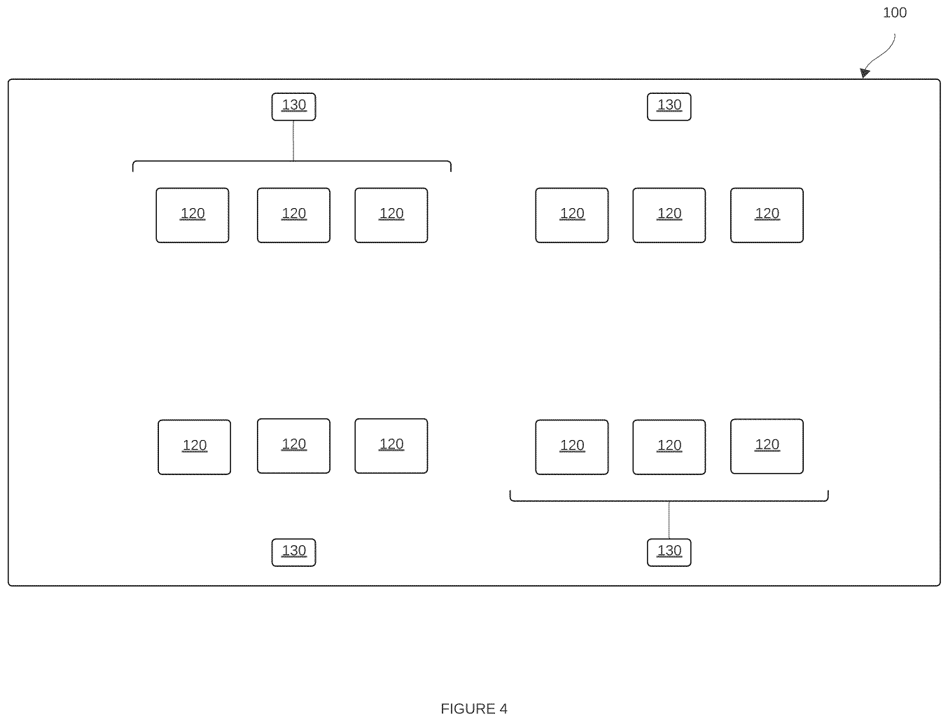

In one or more embodiments, setting the plurality of SoC microcontrollers includes setting a distinct SoC MC proximate to or adjacent to a linear array or series of processing nodes of the plurality of processing nodes, as shown by way of example in FIG. 4. That is, the distinct SoC microcontroller that is placed next to the linear array of processing nodes may be electrically connected to each of the processing nodes within the linear array of processing nodes for managing power requirements of each processing node within the linear array.

In one or more embodiments, the connection of each SoC microcontroller to its corresponding series or group of processing nodes may include multiple conducting traces between a given SoC microcontroller and a corresponding group of processing nodes. In a non-limiting example, the conductive connections between each processing node in a group of processing nodes and a given SoC microcontroller may include a first conductive connection or trace for data communications and a second conductive connection (i.e., a power rail) for delivering power by the SoC microcontroller for a power source to each respective processing node within the group or series.

Additionally, or alternatively, setting the plurality of SoC microcontrollers onto the printed circuit board includes positioning each SoC microcontroller over a power source of the printed circuit board, such as a power plane or dedicated power delivery network. In such embodiments, S250 positioning each of the plurality of SoC microcontrollers in this manner may ensure direct access to power and facilitate more effective management of power distribution to the processing nodes.

Embodiments of the system and/or method can include every combination and permutation of the various system components and the various method processes, wherein one or more instances of the method and/or processes described herein can be performed asynchronously (e.g., sequentially), concurrently (e.g., in parallel), or in any other suitable order by and/or using one or more instances of the systems, elements, and/or entities described herein.

As a person skilled in the art will recognize from the previous detailed description and from the figures and claims, modifications and changes can be made to the preferred embodiments of the invention without departing from the scope of this invention defined in the following claims.

We claim:

1. A method of configuring a printed circuit board, the method comprising:
setting onto a substrate of a printed circuit board:
(A) a plurality of distinct sets of processing nodes,
wherein setting the plurality of distinct sets of processing nodes includes arranging one or more pairs of parallel processing nodes onto the substrate of the printed circuit board, each of the one or more pairs of parallel processing nodes including a first set of processing nodes being arranged parallel to a second set of processing nodes of the plurality of distinct sets of processing nodes;
(B) a plurality of interconnect switches,
wherein setting the plurality of interconnect switches includes centrally interposing one of the plurality of interconnect switches between each of the one or more pairs of parallel processing nodes; and
(C) a plurality of microcontrollers along a peripheral region of the substrate of the printed circuit board surrounding the plurality of distinct sets of processing nodes.

2. The method according to claim 1, further comprising:
(D) setting onto the substrate of the printed circuit board a plurality of sets of interconnect cables, wherein setting the plurality of sets of interconnect cables includes arranging a first set of interconnect cables adjacent a side of a first interconnect switch of the plurality of interconnect switches and arranging a second set of interconnect cables adjacent a side of a second interconnect switch of the plurality of interconnect switches.

3. The method according to claim 2, wherein:
the first set of interconnect cables being configured to operate a first data transfer protocol, and
the second set of interconnect cables being configured to operate a second data transfer protocol that is distinct from the first data transfer protocol.

4. The method according to claim 1, wherein each distinct set of the plurality of distinct sets of processing nodes includes a linear array of processing nodes sequentially disposed on the substrate of the printed circuit board.

5. The method according to claim 1, wherein:
the first set of processing nodes of a first of the one or more pairs of parallel processing nodes comprises a first linear array of processing nodes;
the second set of processing nodes of the first of the one or more pairs of parallel processing nodes comprises a second linear array of processing nodes;
a linear extent of the first linear array of processing nodes is arranged parallel to a linear extent of the second linear array of processing nodes; and
interposing the one of the plurality of interconnect switches between each of the one or more pairs of parallel processing nodes includes interposing a first interconnect switch of the plurality of interconnect switches between the first linear array of processing nodes and the second linear array of processing nodes.

6. The method according to claim 5, wherein setting the plurality of interconnect switches further includes:
positioning a first interconnect switch of the plurality of interconnect switches offset an axis centrally bisecting the first linear array of processing nodes and the second linear array of processing nodes that are parallelly disposed onto the substrate of the printed circuit board.

7. The method according to claim 1, wherein:
the first set of processing nodes of a second of the one or more pairs of parallel processing nodes comprises a first linear array of processing nodes;
the second set of processing nodes of the second of the one or more pairs of parallel processing nodes comprises a second linear array of processing nodes;
a linear extent of the first linear array of processing nodes is arranged parallel to a linear extent of the second linear array of processing nodes; and
interposing the one of the plurality of interconnect switches between each of the one or more pairs of parallel processing nodes includes interposing a second interconnect switch of the plurality of interconnect switches between the first linear array of processing nodes and the second linear array of processing nodes of the second of the one or more pairs of parallel processing nodes.

8. The method according to claim 1, wherein setting the plurality of interconnect switches further includes centrally aligning a first interconnect switch with a second interconnect switch of the plurality of interconnect switches.

9. The method according to claim 1, further comprising:
configuring one or more free spaces on the substrate of the printed circuit board between each processing node of a given linear array of processing nodes and at least one interconnect switch of the plurality of interconnect switches, wherein the one or more free spaces exclude electrical obstructions.

10. The method according to claim 9, wherein the gap on the substrate of the printed circuit board excludes a placement of electrical components between each processing node of the given linear array of processing nodes and the at least one interconnect switch of the plurality of interconnect switches.

11. The method according to claim 1, wherein each of the plurality of microcontrollers is arranged adjacent one distinct set of processing nodes of the plurality of distinct sets of processing nodes.

12. A method of configuring an electronic circuit board, the method comprising:
integrating onto a substrate of an electronic circuit board:
(A) a plurality of distinct sets of processing circuits,
wherein integrating the plurality of distinct sets of processing circuits includes arranging one or more pairs of parallel processing circuits onto the substrate of the electronic circuit board, each of the one or more pairs of parallel circuits including a first set of processing circuits being arranged parallel to a second set of processing circuits of the plurality of distinct sets of processing circuits;
(B) a plurality of interconnect switches,
wherein integrating the plurality of interconnect switches includes centrally interposing one of the plurality of interconnect switches between each of the one or more pairs of parallel processing circuits; and
(C) a plurality of microcontrollers along a peripheral region of the substrate of the electronic circuit board surrounding the plurality of distinct sets of processing circuits.

13. The method according to claim 12, further comprising:
(D) integrating onto the substrate of the electronic circuit board a plurality of sets of interconnect cables, wherein integrating the plurality of sets of interconnect cables includes arranging a first set of interconnect cables adjacent a side of a first interconnect switch of the plurality of interconnect switches and arranging a second set of interconnect cables adjacent a side of a second interconnect switch of the plurality of interconnect switches.

14. The method according to claim 13, wherein:
the first set of interconnect cables being configured to operate a first data transfer protocol, and
the second set of interconnect cables being configured to operate a second data transfer protocol that is distinct from the first data transfer protocol.

15. The method according to claim 12, wherein each distinct set of the plurality of distinct sets of processing circuits includes a series array of processing circuits sequentially disposed on the substrate of the electronic circuit board.

16. The method according to claim 12, wherein:
the first set of processing circuits of a first of the one or more pairs of parallel processing circuits comprises a first series array of processing circuits;
the second set of processing circuits of the first of the one or more pairs of parallel processing circuits comprises a second series array of processing circuits;
a series extent of the first series array of processing circuits is arranged parallel to a series extent of the second series array of processing circuits; and
interposing the one of the plurality of interconnect switches between each of the one or more pairs of parallel processing circuits includes interposing a first interconnect switch of the plurality of interconnect switches between the first series array of processing circuits and the second series array of processing circuits.

17. The method according to claim 16, wherein integrating the plurality of interconnect switches further includes:
positioning a first interconnect switch of the plurality of interconnect switches offset an axis centrally bisecting the first series array of processing circuits and the second series array of processing circuits that are parallelly disposed onto the substrate of the electronic circuit board.

18. The method according to claim 12, wherein:
the first set of processing circuits of a second of the one or more pairs of parallel processing circuits comprises a first series array of processing circuits;
the second set of processing circuits of the second of the one or more pairs of parallel processing circuits comprises a second series array of processing circuits;
a series extent of the first series array of processing circuits is arranged parallel to a series extent of the second series array of processing circuits; and
interposing the one of the plurality of interconnect switches between each of the one or more pairs of parallel processing circuits includes interposing a second interconnect switch of the plurality of interconnect switches between the first series array of processing circuits and the second series array of processing circuits of the second of the one or more pairs of parallel processing circuits.

19. The method according to claim 12, further comprising:
configuring one or more free spaces on the substrate of the electronic circuit board between each processing circuit of a given series array of processing circuits and at least one interconnect switch of the plurality of interconnect switches, wherein the one or more free spaces exclude electrical obstructions, wherein the gap on the substrate of the electronic circuit board excludes a placement of electrical components between each processing circuit of the given series array of processing circuits and the at least one interconnect switch of the plurality of interconnect switches.

20. A method comprising:
placing onto a substrate of an electronic circuit board:
(A) a plurality of distinct sets of processing nodes,
wherein placing the plurality of distinct sets of processing nodes includes arranging a pair of parallel processing nodes onto the substrate of the electronic circuit board, the pair of parallel processing nodes including a first array of processing nodes being arranged parallel to a second array of processing nodes of the plurality of distinct sets of processing nodes;
(B) an interconnect switch,
wherein placing the interconnect switch includes centrally interposing the interconnect switch between the pair of parallel processing nodes; and
(C) a plurality of microcontrollers along a peripheral region of the substrate of the electronic circuit board surrounding the plurality of distinct sets of processing nodes.
